(19) United States
(12) Patent Application Publication
(10) Pub. No.: US 2016/0141478 A1
(43) Pub. Date: May 19, 2016

(54) LAMINATED THERMOELECTRIC CONVERSION ELEMENT AND MANUFACTURING METHOD THEREFOR

(71) Applicant: Murata Manufacturing Co., Ltd., Nagaokakyo-shi (JP)

(72) Inventors: Takanori Nakamura, Nagaokakyo-shi (JP); Shuichi Funahashi, Nagaokakyo-shi (JP)

(21) Appl. No.: 15/005,307

(22) Filed: Jan. 25, 2016

Related U.S. Application Data
(63) Continuation of application No. PCT/JP2014/068889, filed on Jul. 16, 2014.

(30) Foreign Application Priority Data
Aug. 5, 2013 (JP) 2013-162615

(51) Int. Cl. H01L 35/04; H01L 35/34

(52) U.S. Cl. CPC H01L 35/04; H01L 35/34

(57) ABSTRACT

A laminated thermoelectric conversion element is configured to generate electricity from a difference in temperature with respect to a heat-transfer direction. The thermoelectric conversion element includes opposed first and second surfaces which extend in the heat-transfer direction. Respective external electrodes are provided on the first and second surfaces for outputting electricity generated from the temperature difference. At least one of the first and second surfaces is provided with a mark which makes it possible to visually determine the location of the high-temperature side and the low-temperature side with respect to the heat-transfer direction as well as the polarity of the electricity generated.

### CROSS REFERENCE TO RELATED APPLICATIONS

The present application is a continuation of International application No. PCT/JP2014/068889, filed Jul. 16, 2014, which claims priority to Japanese Patent Application No. 2013-162615, filed Aug. 5, 2013, the entire contents of each of which are incorporated herein by reference.

### TECHNICAL FIELD

The present invention relates to a laminated thermoelectric conversion element and a method for manufacturing the element.

### BACKGROUND ART

An example of an invention that relates to an extraction electrode of a thermoelectric module is given in Japanese Patent Application Laid-Open No. 2003-8085.

An electrolytic capacitor configured to differ in lead shape between positive (+) and negative (−) poles in order to prevent the polarities from being reversed before mounting onto a substrate is described in Japanese Patent Application Laid-Open No. 10-144568.

An example of a laminated thermoelectric conversion element is given in Japanese Patent Application Laid-Open No. 2009-124030. This laminated thermoelectric conversion element has alternating p-type and n-type oxide thermoelectric conversion material layers. Insulating layers are disposed between adjacent n-type and p-type material layer but extend over only a part of those interfaces to form a meandering current path as show, for example, in FIG. 1 thereof.

As shown in FIG. 20, the laminated thermoelectric conversion element generates a potential difference as a function of a temperature difference between high and low temperature sides 10 and 12 due to the Seebeck effect within each of the p-type and n-type oxide thermoelectric conversion material layers. The p-type oxide thermoelectric conversion material is, for example, a p-type thermoelectric semiconductor. The n-type oxide thermoelectric conversion material is, for example, an n-type thermoelectric semiconductor. The Seebeck coefficient of the p-type thermoelectric semiconductor is positive, whereas the Seebeck coefficient of the n-type thermoelectric semiconductor is negative.

The p-type oxide thermoelectric conversion material and the n-type oxide thermoelectric conversion material are electrically connected alternately, and the potential differences generated in the respective layers are thus summed in series resulting in a relatively large potential difference. The potential difference generated in this way can be extracted externally through a pair of external electrodes (not shown). As a result, the laminated thermoelectric conversion element can generate electricity from the given difference in temperature.

### SUMMARY OF THE INVENTION

### Problem to be Solved by the Invention

As shown in FIGS. 20 and 21, the polarity of the electric current is a function of the order of the p-type and the n-type layers. When the laminated thermoelectric conversion element shown in FIG. 20 is rotated by 180° around a rotation axis perpendicular to the plane of paper, the electric current obtained has the same polarity. However, when the laminated thermoelectric conversion element shown in FIG. 20 is rotated by 180° around a rotation axis extending vertically in FIG. 20, the electric current obtained has a reverse polarity as shown in FIG. 21. It is important, therefor to avoid misorientation of the thermoelectric conversion element to avoid switched polarities.

The shape of a typical laminated thermoelectric conversion element, is cuboid as shown, by way of example, in FIG. 22, and respective external electrodes (not shown) are provided on the opposed surfaces 10, 12. The cuboid is quite small, typically several mm on a side.

In order to make it easy to determine which sides of the cuboid correspond to the high and low temperature sides on the one hand and the + and − electrodes on the other it may be designed so that vertical, horizontal, and height dimensions A, B, and C differ from each other. However, it is not possible to visually discriminate between the upper and lower surfaces, or between the right and left surfaces, because of the symmetrical shape as a whole.

The external electrodes are typically formed by electrolytic plating the entire outer surface of the thermoelectric conversion element and then removing the electrodes from those surfaces not requiring an electrode by polishing. Just after the electrolytic plating is carried out, all of the six surfaces are totally covered with the metal films and the surfaces all have similar metallic luster. Thus, it becomes impossible to visually determine which surface is the high-temperature side, or which surface is the + pole.

When a thermoelectric conversion element is designed so that the vertical, horizontal, and height dimensions differ from each other, those dimensions can be used as clues as to which opposing surfaces are the high and low temperature sides and which opposing surfaces are the ones on which the external electrodes should be formed. However, it is not possible to specify which one of the two opposed temperature surfaces corresponds to the high-temperature side and the low-temperature side and which of the opposed external electrode surfaces correspond to the + and − sides.

In addition, when any of the vertical, horizontal, and height dimensions are equal, it becomes more difficult to identify the respective surfaces.

Because of this problem, an electrical test is used to determine the direction of current generated by the thermoelectric conversion element. More particularly, a temperature difference is applied to the two opposing surfaces that are the high and low temperature surfaces and a respective probe is brought into contact with each of the surfaces on which an electrode should be formed to determine the direction of the current produced by the temperature difference. Since the thermoelectric conversion element is small, this is a difficult task.

Therefore, an object of the present invention is to make it easy to identify which surface is the high-temperature side, which surface is the low-temperature side, which surface is the + electrode side and which surface is the − electrode side.

### Means for Solving the Problem

In order to achieve the object mentioned above, the laminated thermoelectric conversion element in accordance with the present invention is a laminated thermoelectric conversion element configured to generate electricity from a difference in temperature with respect to a heat-transfer direction. The element includes first and second opposed surfaces which preferably extend in the heat-transfer direction. First and second external electrodes (for outputting electricity generated from the difference in temperature) are provided on the first and second surfaces, respectively. At least one of the first and second surfaces is provided with a visual mark which makes it possible to determine the high-temperature side and low-temperature side surfaces as well as the polarity of the electricity generated.

### Advantageous Effect of the Invention

The present invention is configured to make it possible to visually determine the high-temperature side and low-temperature side of the thermoelectric conversion element as well as the polarity of electricity generated.

### BRIEF EXPLANATION OF DRAWINGS

FIG. 1 is an explanatory diagram of a laminated thermoelectric conversion element according to First Embodiment of the invention.

FIG. 2 is a side view of the laminated thermoelectric conversion element according to the First Embodiment as viewed from a first surface.

FIG. 3 is a side view of the laminated thermoelectric conversion element according to the First Embodiment as viewed from a second surface.

FIG. 4 is an explanatory diagram of a laminated thermoelectric conversion element according to a Second Embodiment of the present invention.

FIG. 5 is a side view of the laminated thermoelectric conversion element according to the Second Embodiment as viewed from a first surface.

FIG. 6 is a side view of the laminated thermoelectric conversion element according to the Second Embodiment as viewed from a second surface.

FIG. 7 is a side view of a first modification example of the laminated thermoelectric conversion element according to the Second Embodiment as viewed from a first surface.

FIG. 8 is a side view of a second modification example of the laminated thermoelectric conversion element according to the Second Embodiment as viewed from a first surface.

FIG. 9 is a side view of a third modification example of the laminated thermoelectric conversion element according to the Second Embodiment as viewed from a first surface.

FIG. 10 is a side view of a fourth modification example of the laminated thermoelectric conversion element according to the Second Embodiment as viewed from a first surface.

FIG. 11 is a flowchart of a method for manufacturing a laminated thermoelectric conversion element according to a Third Embodiment of the present invention.

FIG. 12 is an explanatory diagram of a first step of the method for manufacturing a laminated thermoelectric conversion element according to the Third Embodiment.

FIG. 13 is an explanatory diagram of a second step of the method for manufacturing a laminated thermoelectric conversion element according to the Third Embodiment.

FIG. 14 is a plan view of a pattern A in applying an insulating paste to an outermost surface material layer for use in the method for manufacturing a laminated thermoelectric conversion element according to the Third Embodiment.

FIG. 15 is a plan view of a pattern B in applying an insulating paste to an outermost surface material layer for use in the method for manufacturing a laminated thermoelectric conversion element according to the Third Embodiment.

FIG. 16 is a perspective view of a large-sized stacked body obtained in the course of the method for manufacturing a laminated thermoelectric conversion element according to the Third Embodiment.

FIG. 17 is a plan view of a pattern C in applying a metal paste to an outermost surface material layer for use in the method for manufacturing a laminated thermoelectric conversion element according to the Third Embodiment.

FIG. 18 is a plan view of a pattern D in applying a metal paste to an outermost surface material layer for use in the method for manufacturing a laminated thermoelectric conversion element according to the Third Embodiment.

FIG. 19 is a plan view of a pattern E in applying an insulating paste to an outermost surface material layer for use in the method for manufacturing a laminated thermoelectric conversion element according to the Third Embodiment.

FIG. 20 is a first explanatory diagram of the operation of a laminated thermoelectric conversion element based on the prior art.

FIG. 21 is a second explanatory diagram of the operation of a laminated thermoelectric conversion element based on the prior art.

FIG. 22 is a perspective view of a laminated thermoelectric conversion element based on the prior art.

### BEST MODE FOR CARRYING OUT THE INVENTION

### First Embodiment

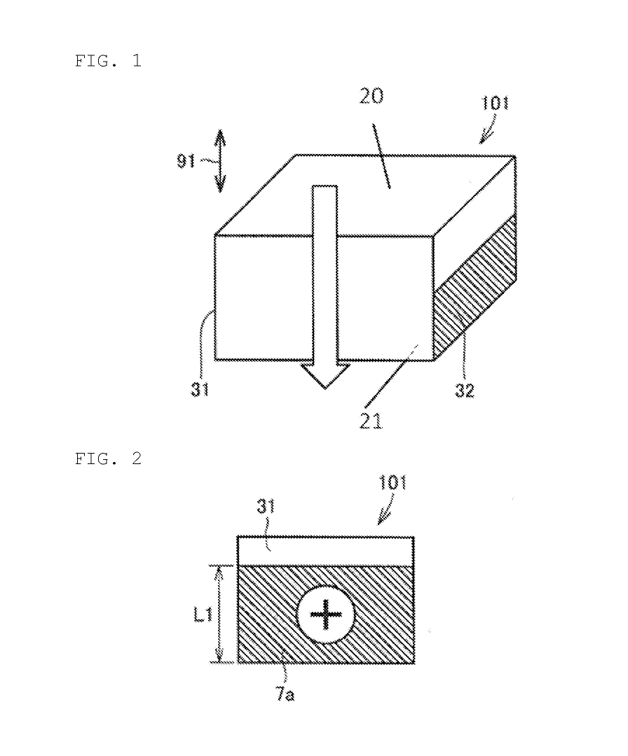

A laminated thermoelectric conversion element according to a First Embodiment of the present invention will now be described with reference to FIGS. 1 to 3.

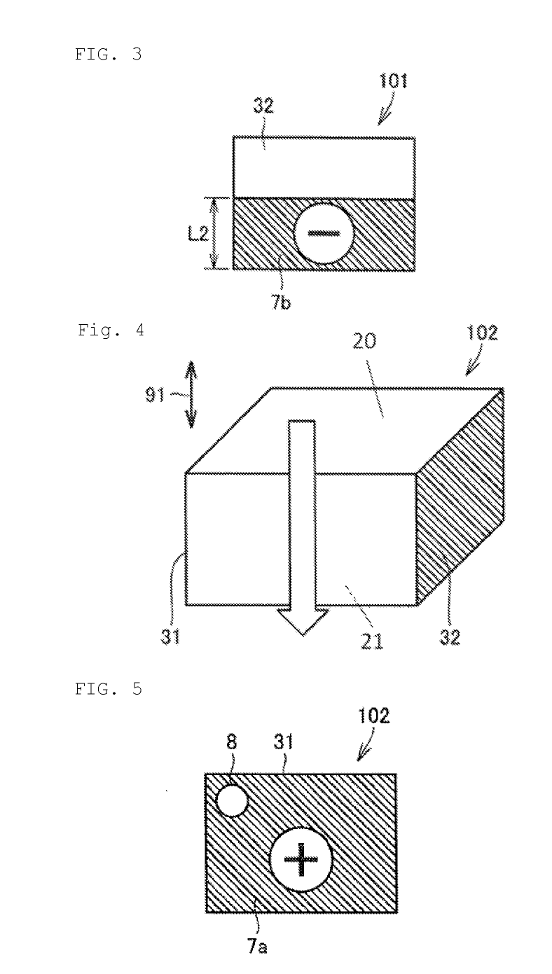

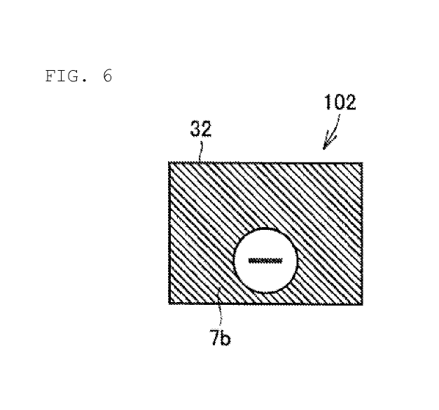

The laminated thermoelectric conversion element 101 is configured to generate electricity from a difference in temperature with respect to the heat-transfer direction 91. It includes opposing first and second electrode bearing surfaces 31 and 32 which are preferably generally parallel to the heat-transfer direction. FIG. 2 shows a first electrode bearing surface 31 while FIG. 3 shows the second electrode bearing surface 32. The first and second electrode bearing surfaces 31 and 32 are provided with respective external electrodes 7a, 7b for outputting electricity generated from the difference in temperature between the high and low temperature side surfaces 20, 21, respectively. At least one of the first and second surfaces 31, 32 is provided with a mark (as used herein, a mark is any visual feature perceptible by a human or machine) which makes it possible to visually determine which surface is the high-temperature side surface and which surface is the low-temperature side surface as well as the polarity of the electricity generated. It is to be noted that a symbol indicating + or − in a circle as shown in FIG. 2 or 3 is intended to identify the polarity of the external electrode for the sake of explanation convenience. It is not intended to represent any visual shape appearing on the surfaces. Also in the drawings below, the same is intended when external electrodes have the symbols shown.

In the present embodiment, the visual marks are differences in at least one of the position, size, and shape of the external electrodes. In the example shown in FIGS. 2 and 3, the external electrodes 7a, 7b differ in size. More specifically, the external electrode 7a provided on the first surface 31 extends over a length L1 from a lower end in the figure, whereas the external electrode 7b provided on the second surface 32 extends over a length L2 from a lower end in the figure. This means L1≠L2. The difference between L1 and L2 is preferably sufficiently significant to be easily visually perceived.

The external electrodes 7a, 7b are preferably asymmetrical with respect to a horizontal center line extending through the first and second surfaces 31, 32, respectively in FIGS. 2 and 3. As long as the external electrodes are provided to be visually discriminable vertically, it is possible to simultaneously identify both the polarity of the electricity and the high-temperature side surface and the low-temperature side surface.

As long as the external electrodes 7a, 7b differ in their position (relative to the side surface on which they are formed), size and/or shape, and the configuration is simple, they can act as clear visual marks indicating the polarity of the electrode side surfaces and high and low temperature side surfaces without increasing the number of parts.

In order to form an external electrode so as to cover only a portion of the side surface on which it is formed, an insulating film is formed on the portion where the external electrode should not be formed. When electrolytic plating is carried out, the metal film does not adhere to the portion covered with the insulating film but does adhere to the remainder of the side surface (i.e., the exposed part of the semiconductor material). As a result, a metal film is formed only on a portion of the side surface.

In the case of trying to simultaneously form a metal film on all of the six surfaces by electrolytic plating, and then remove the metal film by polishing the four surfaces where no external electrode is required, according to the present embodiment, the four surfaces to be polished can be easily identified since no metal film adheres to the portion of the side surface having the insulating film formed thereon.

The external electrodes may be, for example, Ni films. The Ni films can be formed by electrolytic Ni plating.

### Second Embodiment

A laminated thermoelectric conversion element 102 according to a Second Embodiment of the present invention will be described with reference to FIGS. 4 to 6. FIG. 4 generally shows the laminated thermoelectric conversion element 102 according to the present embodiment.

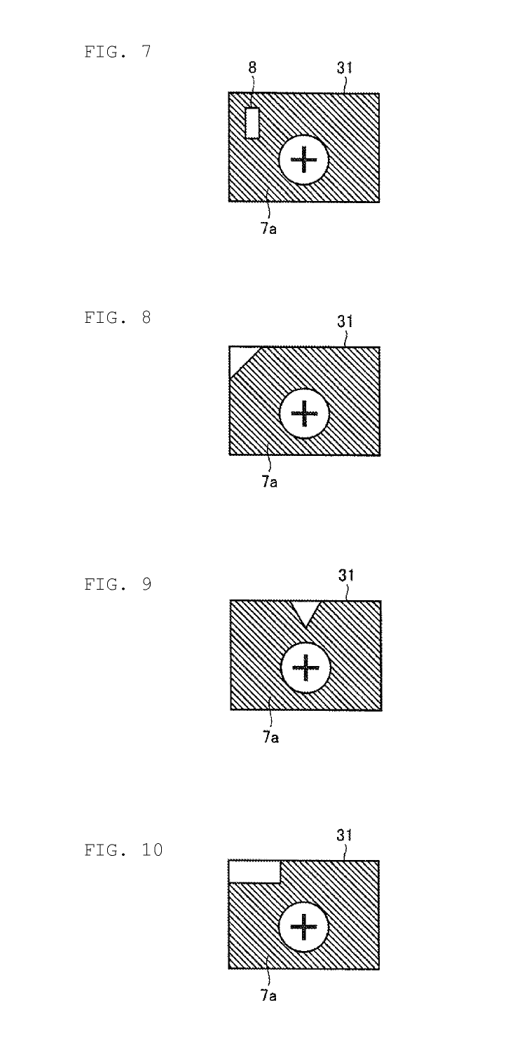

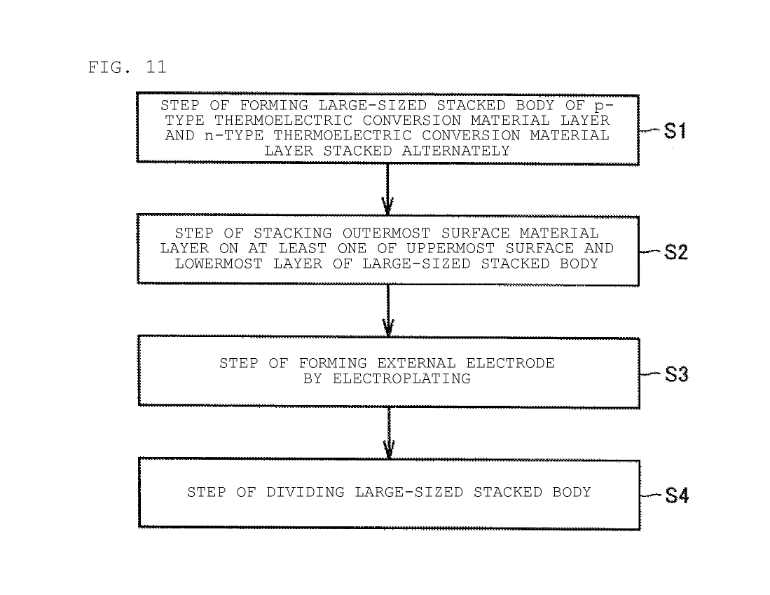

The laminated thermoelectric conversion element 102 is configured to generate electricity from a difference in temperature with respect to the heat-transfer direction 91. The element 102 includes first and second opposed electrode bearing surfaces 31 and 32 which preferably extend generally parallel to the heat-transfer direction. FIG. 5 shows the first surface 31 and FIG. 6 shows the second surface 32. The first and second surfaces 31 and 32 are respectively provided with external electrodes 7a, 7b for outputting electricity generated from the difference in temperature between opposing surfaces 20 and 21. At least one of the first and second surfaces 31 and 32 is provided with a mark which makes it possible to visually determine the high-temperature side surface and low-temperature side surface with respect to the heat-transfer direction 91 as well as the polarity of the electricity generated.

In the present embodiment, the mark is a shaped pattern 8 provided on at least one of the pair of external electrodes 7a, 7b. As shown in FIGS. 5 and 6, the external electrode 7b entirely covers the second surface 32 while the external electrode 7a covers only a portion of the first surface 31. More particularly, a shape pattern 8 is formed by the absence of metal film. The shape pattern 8 is provided in an upper-left position of the first surface 31 in FIG. 5. As long as the shape pattern 8 is provided in a manner that can be easily visually discriminated it is possible to identify the polarity of the electricity as well as the location of the high-temperature side surface and low-temperature side surfaces.

The present embodiment can also achieve the same effect as described in First Embodiment.

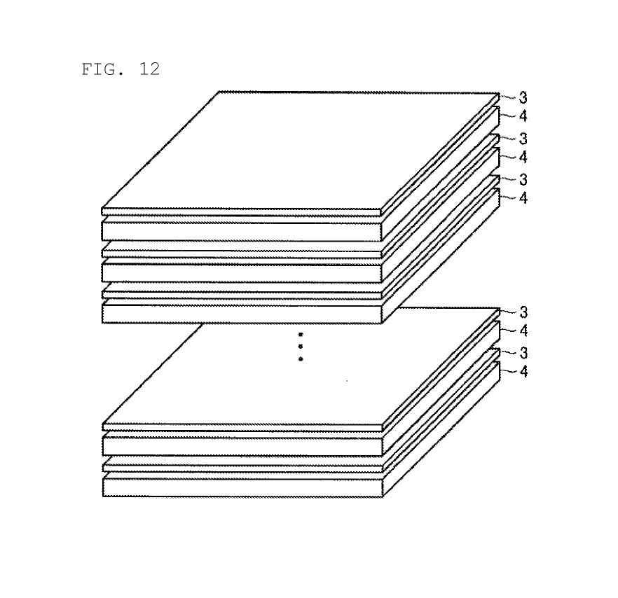

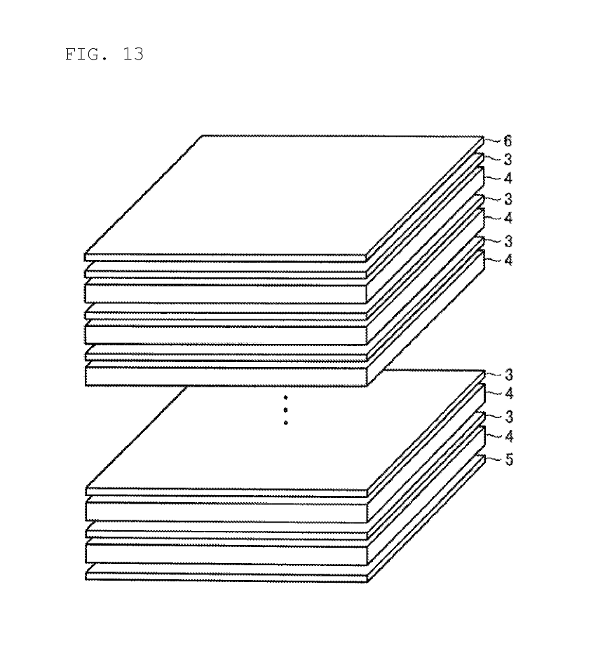

While an example of providing only a single shape pattern 8 in the form of a dot has been given herein, the shape pattern of the mark may have any other shape or arrangement that will serve as a visual identifying mark. For example, the shape pattern of the mark may have a rectangular shape as shown in FIG. 7. Alternatively, and without limitation, the mark may be a notch provided in accordance with a fixed rule as shown in FIGS. 8, 9, and 10. These are all examples of possible shapes and arrangements and the invention is not limited thereto.

While examples of providing the positive external electrode with a pattern as a mark have been illustrated in FIGS. 5 through 10, the invention is not limited to the positive external electrode. The negative external electrode may alternatively or additionally be provided with a pattern as a mark. Both of the positive and negative external electrodes may be respectively provided with different mark patterns.

### Third Embodiment

A method for manufacturing laminated thermoelectric conversion element according to a Third Embodiment in accordance with the present invention will be described with reference to FIGS. 11 to 16, etc. FIG. 11 shows a flowchart of a method for manufacturing a laminated thermoelectric conversion element according to the present embodiment.

A method for manufacturing the laminated thermoelectric conversion element according to the present embodiment includes a step 1 of preparing a composite stacked body which will subsequently be divided into a plurality of thermoelectric conversion elements configured to generate electricity from a difference in temperature relative to a heat-transfer direction. The composite stacked body is preferably formed by alternately stacking p-type and n-type thermoelectric conversion material layers with insulating layers disposed between parts of the interface between adjacent layers so as to provide a continuous electrical connection in a meander form.

In step S2 an outermost surface material layer is stacked on at least one of the uppermost surface and lowermost surface of the composite stacked body. The outermost surface material layer defines and includes a region where external electrodes for outputting electricity generated from the temperature difference is to be formed.

In step S3 an external electrode is formed by electrolytic plating the region and in step S4 the composite stacked body is divided into individual thermoelectric conversion layers with the outermost surface material layer being divided into respective regions for the individual laminated thermoelectric conversion elements. Before the dividing step S4, a mark or a base for a mark is formed on each region corresponding to a respective one of the thermoelectric layers which mark or base for a mark will make it possible to visually determine the high-temperature side surface, the low-temperature side surface and the polarity of electricity generated in the individual laminated thermoelectric conversion element after the division step.

Details will be described below with reference to the drawings. An aspect of the step S1 is shown in FIG. 12. In this step, p-type thermoelectric conversion material layers 3 which are partially covered with an insulating layer and n-type thermoelectric conversion material layers 4 which are partially covered with an insulating layer are alternately stacked to form a large-sized stacked body. The thickness of the p-type thermoelectric conversion material layers 3 are preferably significantly different than the thickness of the n-type thermoelectric conversion material layers 4. This is done to make the electrical resistance value uniform in the p-type part and n-type part of the element as a whole, because the electrical resistivity differs between the both layers due to the use of materials of different compositions. The p-type or n-type material layers which has a higher electrical resistivity is thicker than the other type of material layer. The p-type thermoelectric conversion material layers 3 and the n-type thermoelectric conversion material layers 4 are each a composite sheet corresponding to a plurality of thermoelectric conversion elements. The composite stacked body corresponds to a plurality of thermoelectric conversion elements. Therefore, the composite stacked body includes a plurality of meandering electrical connection routes.

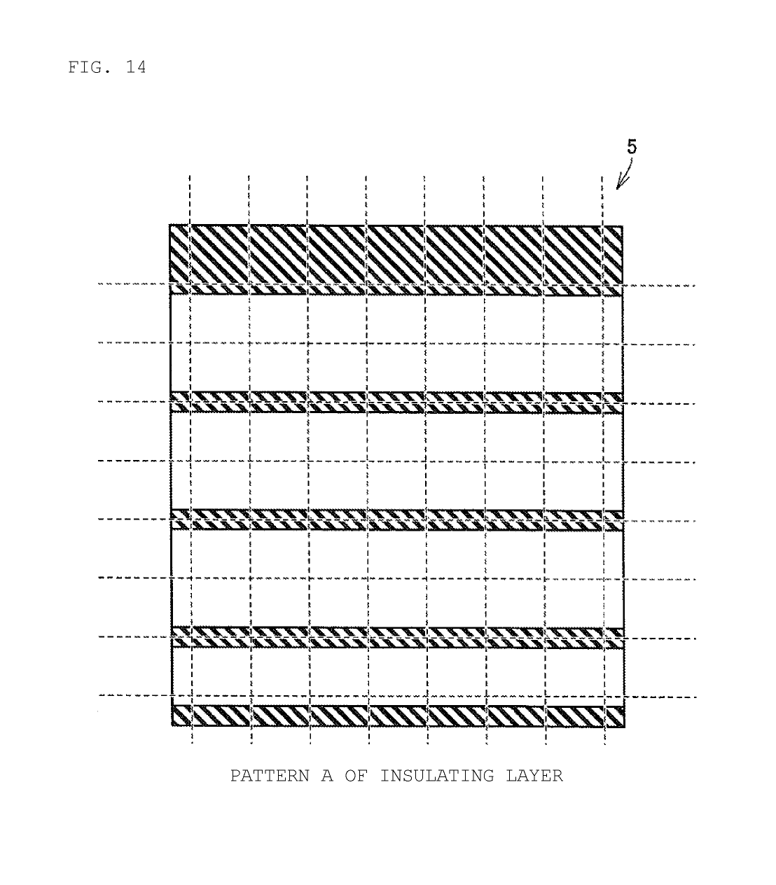

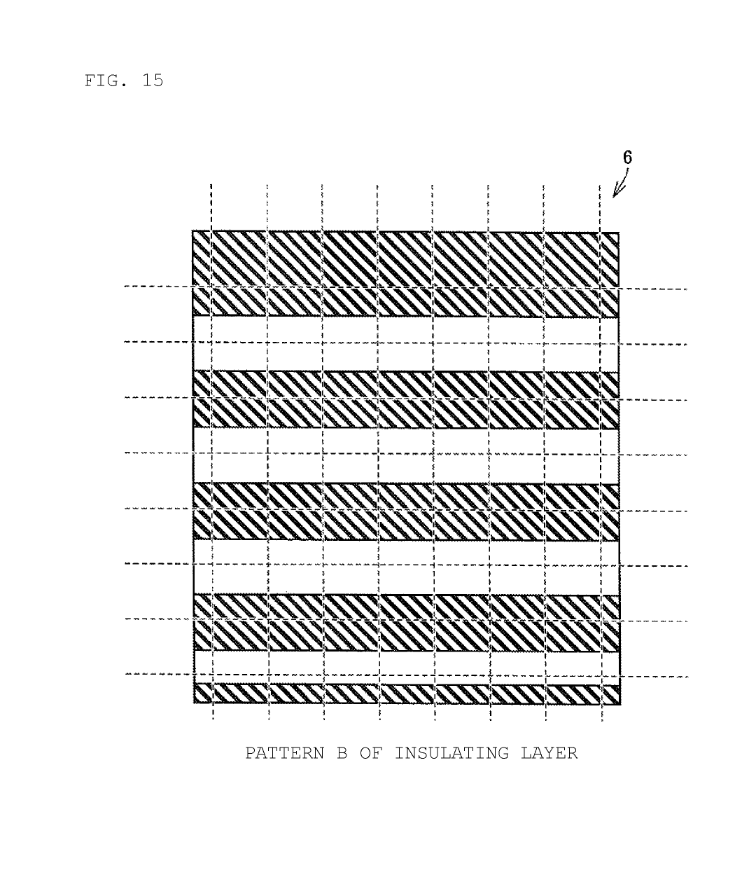

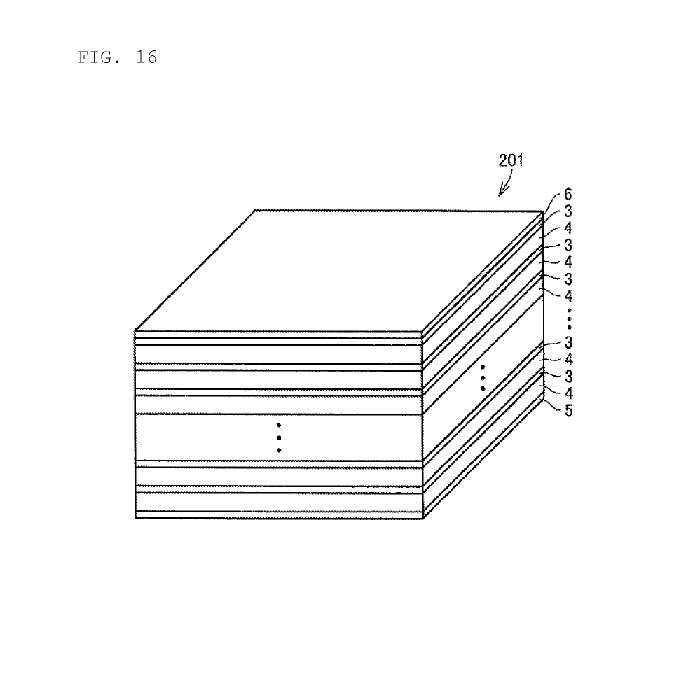

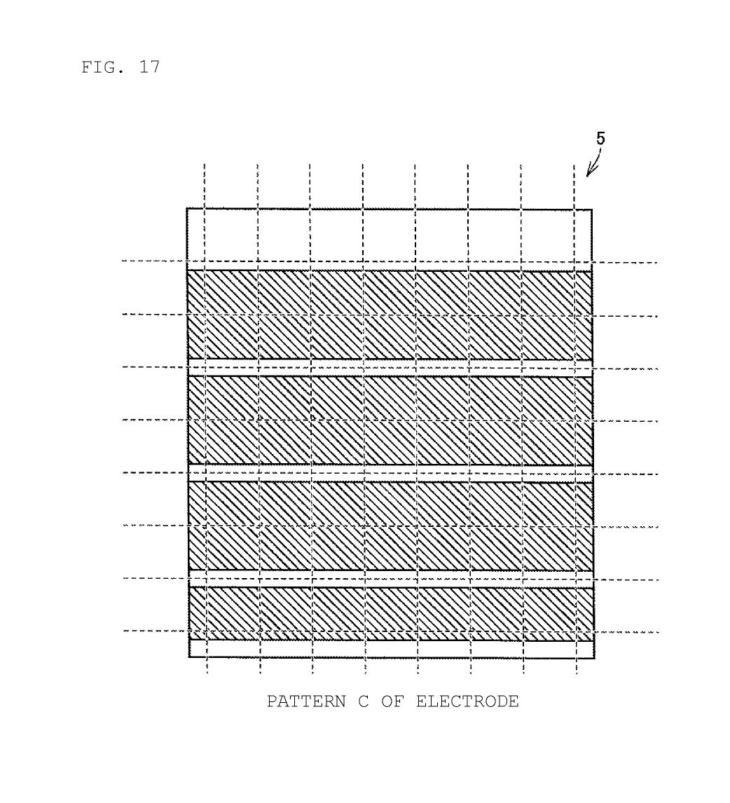

As the step S2, the outermost surface material layers 5, 6 (FIG. 13) are regions on which external electrodes for outputting the electricity generated from the temperature difference are to be formed. The outermost surface material layer 5 is disposed at the bottom of the stacked body, whereas the outermost surface material layer 6 is disposed at the top thereof (as viewed in FIG. 13). FIG. 14 shows a plan view of the outermost surface material layer 5. FIG. 15 shows a plan view of the outermost surface material layer 6. In each of FIGS. 14 and 15, an insulating layer is applied to thickly hatched regions. The dashed lines indicate section lines for dividing the composite stacked body into individual stacked bodies in the step S4.

As shown in FIGS. 14 and 15, the insulating layers on the outermost surface material layers 5, 6 have different patterns. Although the patterns of insulating layers are not intended to correspond to external electrodes themselves, the difference between the patterns of insulating layers shown in FIGS. 14 and 15 corresponds to the base for a mark which makes it possible to visually determine the heat-transfer direction and the polarity of electricity generated in an individual laminated thermoelectric conversion element even after the division.

The steps S1 and S2 need not be carried out in this order. They may be carried in the reverse order or performed partially or entirely in a simultaneously parallel manner. The lowermost, outermost surface material layer 5 may be first placed on a work station, the p-type thermoelectric conversion material layers 3 and the n-type thermoelectric conversion material layers 4 may be alternately stacked thereon, and finally, the outermost surface material layer 6 may be formed on the uppermost surface.

FIG. 16 shows a large-sized stacked body 201 at the point of completion of the foregoing steps. Next, the large-sized stacked body 201 is divided in step S4. The dividing operation may be performed by any known or future developed technique such as with a dicing saw. In step S4, the body is divided as indicated by the dashed line in FIGS. 14 and 15.

The stacked body is subjected to firing and electrolytic plating. Through the electrolytic plating, metal films also adhere to the four surfaces on which no external electrode is to be formed and the metal films on those four surfaces are removed by polishing. The metal films are left on at least portions of the two surfaces on which external electrodes are to be formed. These films are not covered with the insulating film and serve as the external electrodes.

In this way, the laminated thermoelectric conversion element 101 shown in FIGS. 1 through 3 can be obtained.

In the present embodiment, the mark is preferably formed before dividing the large-sized stacked body, and the heat-transfer direction and the polarity of electricity generated in the individual laminated thermoelectric conversion element can be determined by the visual appearance of the thermoelectric conversion element after the division.

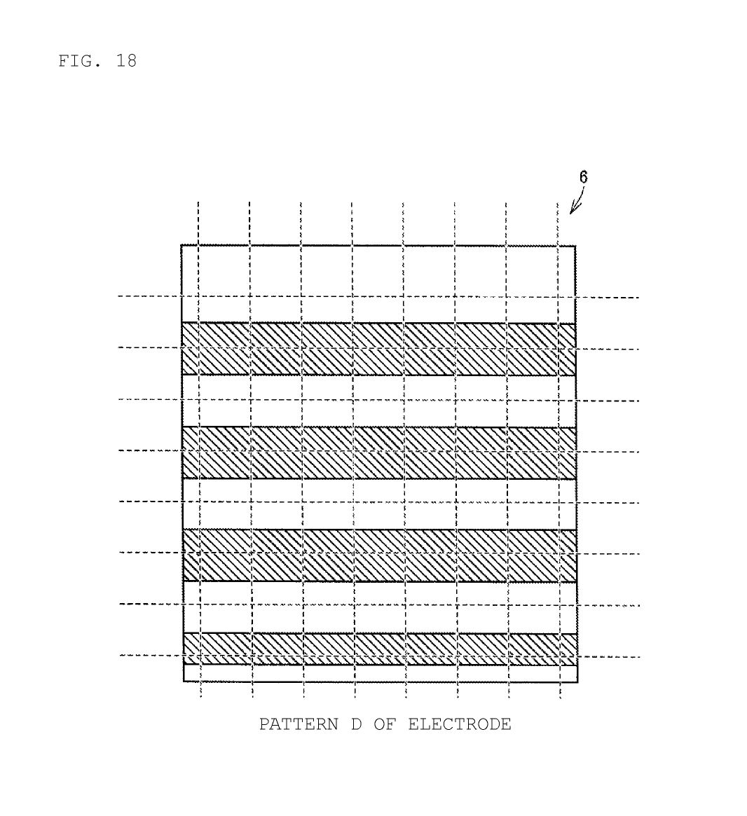

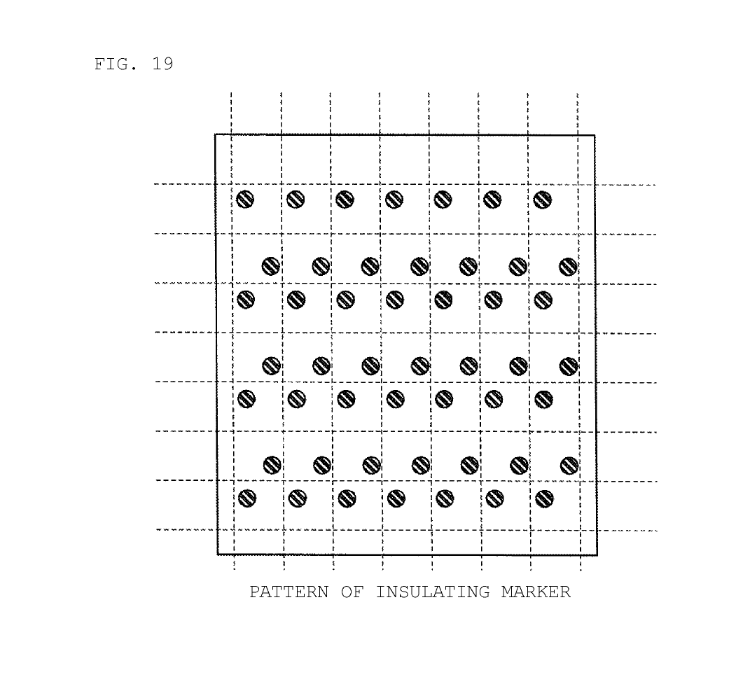

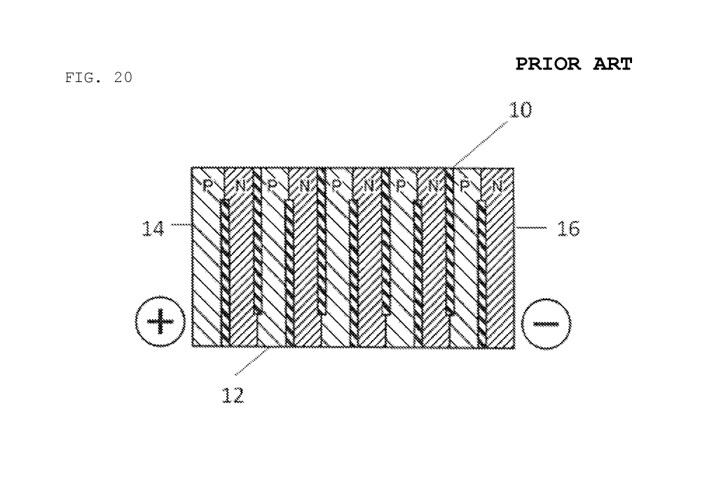

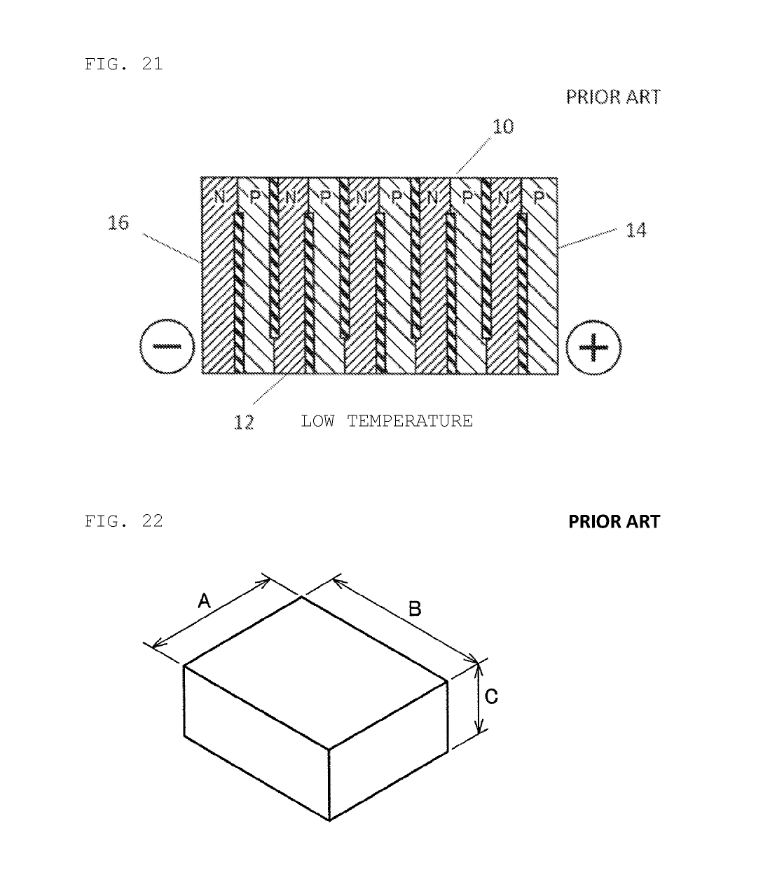

While the different patterns of insulating layers are formed on the outermost surface material layers so that the metal films are formed in the different patterns in the electrolytic plating subsequently carried out in the present embodiment, a metal paste may be applied to the outermost surface material layers in desired patterns. In such a case, for example, as shown in FIGS. 17 and 18, the metal paste may be applied to provide respective different patterns on the two surfaces. The metal paste is subsequently turned into metal films by firing.

### Experimental Example

A metal Ni powder and a metal Mo powder were prepared as starting raw materials for the p-type thermoelectric conversion material. On the other hand, La₂O₃, SrCO₃, and TiO₂ were prepared as starting raw materials for the n-type thermoelectric conversion material. These starting raw materials were used, and weighed so as to provide the p-type and n-type thermoelectric conversion materials of the following compositions.

The p-type composition is:

Ni_{0.9}Mo_{0.1}20wt %+(Sr_{0.965}La_{0.035})TiO₃80 wt %

The n-type composition is:

(Sr_{0.965}La_{0.035})TiO₃

For the n-type composition, the raw material powder was mixed in a ball mill with pure water as a solvent over 16 hours. The obtained slurry was dried, and then subjected to calcination at 1300° C. in the atmosphere. The obtained n-type powder and the raw materials for the p-type powder were each subjected to grinding in a ball mill over 5 hours. The obtained powders were further mixed over 16 hours with the addition of an organic solvent, a binder, etc. thereto, and the obtained slurry was formed into p-type and n-type thermoelectric conversion material sheets using a doctor blade.

A Zr_{0.97}Y_{0.03}O₂ powder, varnish, and a solvent were mixed as materials for the insulating layers, and prepared as a paste with a roll mill. The so prepared materials were used as an “insulating paste”.

The insulating paste was applied to the p-type and n-type thermoelectric conversion material sheets in the patterns shown in FIG. 14 (hereinafter, referred to as a “pattern A”), FIG. 15 (hereinafter, referred to as a “pattern B”), and FIG. 19 (hereinafter, referred to as a “pattern E”). Each paste was applied to be 10 μm in thickness. In FIG. 19, the dotted pattern formed by an insulating layer is also referred to as an insulating marker. In addition, for other samples, a Ni paste was applied in the patterns shown in FIG. 17 (hereinafter, referred to as a “pattern C”) and FIG. 18 (hereinafter, referred to as a “pattern D”) also to a thickness of 10 μm. The Ni paste was used to form Ni films as external electrodes.

These thermoelectric conversion material sheets were stacked so as to provide outermost layers in combination as shown in Table 1, and then subjected to temporary pressure bonding to prepare stacked bodies with different patterns exposed as outermost layers. The stacked body in this stage is also referred to as a “green body”.

TABLE 1

| | |
|---|---|
| Sample | Combination of Outermost Layers |

| | | |
|---|---|---|
| Example 1 | Pattern C | Pattern D |
| Example 2 | Pattern A | Pattern B |
| Example 3 | Pattern A | No Insulating Layer |
| Example 4 | Pattern E | No Insulating Layer |
| Comparative | Pattern C | Pattern C |
| Example | | |

50 pairs of p-type and n-type layers within each element was provided. An element close to a conventional structure was made as a comparative example. This comparative example was obtained from the Ni paste applied in the pattern C to both surfaces of the outermost layers.

The stacked body prepared was cut into a predetermined size with a dicing saw.

The cut stacked body was subjected to pressure bonding at 180 MPa by an isostatic press method, thereby providing a compact.

The obtained compact was subjected to degreasing at 270° C. in the atmosphere. Thereafter, a fired body was obtained by firing at 1200 to 1300° C. in a reducing atmosphere with an oxygen partial pressure of 10⁻¹⁰ to 10⁻¹⁵ MPa. The applied Ni paste films were fired to turn into Ni films. Among the fired bodies obtained, for Example 1 and Comparative Example, the four surfaces other than surfaces with external electrodes formed were polished to remove the excess Ni films, thereby preparing thermoelectric conversion elements provided with the external electrodes only on the two surfaces.

For Examples 2, 3, and 4, electrolytic Ni plating was carried out. Ni films were formed on regions of the surfaces which were not covered with insulating layer. Marks were formed on the surfaces provided with the bases for marks. Among the six surfaces, four were polished, excluding the surface with the mark and the surface opposed thereto. In this way, the laminated thermoelectric conversion elements were prepared.

The formation of the laminated thermoelectric elements structured described above has eliminated mistakes on the discrimination of high-temperature side/low-temperature side, and eliminated mistakes on the polarity of electricity generated, thereby increasing reliability. In addition, the formation has succeeded in skipping the step of confirming polarity conventionally by applying a probe to individual elements.

It is to be noted that the embodiments disclosed therein are considered by way of example in all respects, but not to be considered limiting. The scope of the present invention is specified by the claims, but not the foregoing description, and considered to encompass all modifications within the spirit and scope equivalent to the claims.

1. A laminated thermoelectric conversion element configured to generate electricity from a difference in temperature with respect to a heat-transfer direction, the element comprising:
first and second opposed surfaces;
first and second external electrodes provided on the first and second surfaces, respectively, for outputting electricity generated from the temperature difference; and
a visually perceptible mark provided on at least one of the first and second surfaces which makes it possible to visually determine the high-temperature and low temperature sides of the thermoelectric conversion element with respect to the heat-transfer direction as well as a polarity of the electricity generated.

2. The laminated thermoelectric conversion element according to claim 1, wherein the mark is the fact that the first and second external electrodes differ in at least one of their position on the respective surface on which they are formed, their size and their shape.

3. The laminated thermoelectric conversion element according to claim 1, wherein the mark is a shape pattern provided on at least one of the first and second external electrodes.

4. The laminated thermoelectric conversion element according to claim 1, wherein the mark is defined by one or more characteristics of at least one of the electrodes.

5. The laminated thermoelectric conversion element according to claim 4, wherein the mark is at least one of the size, location or shape of the at least one of the electrodes.

6. The laminated thermoelectric conversion element according to claim 5, wherein the mark is a shape formed within the boundaries of the at least one of the electrodes.

7. A method for manufacturing a plurality of laminated thermoelectric conversion elements configured to generate electricity from a difference in temperature with respect to a heat-transfer direction of the thermoelectric conversion elements, the method comprising:
forming a composite stacked body by alternately stacking p-type thermoelectric conversion material layers which are partially covered with an insulating layer and n-type thermoelectric conversion material layers which are partially covered with an insulating layer, so as to provide a continuous electrical path having a meander form;
forming on at least one of an uppermost surface and a lowermost surface of the composite stacked body, an outermost surface material layer;
forming a respective external electrode for each of the plurality of laminated thermoelectric conversion elements on the outermost surface material layer by electrolytic plating at the outermost surface material layer;
forming a visual mark or a base for a visual mark on each external electrode which makes it possible to visually determine the high-temperature side and low-temperature side of the respective thermoelectric conversion element with respect to the heat-transfer direction and a polarity of electricity generated in the respective laminated thermoelectric conversion element as a function of the temperature difference applied to that thermoelectric conversion element; and
dividing the composite stacked body into the individual laminated thermoelectric conversion elements.

8. The method according to claim 7, wherein the visual mark is the fact that the first and second external electrodes differ in at least one of their position on the respective surface on which they are formed, their size and their shape.

9. The method according to claim 7, wherein the visual mark is a shape pattern provided on at least one of the first and second external electrodes.

10. The method according to claim 7, wherein the visual mark is defined by one or more characteristics of at least one of the electrodes.

11. The method according to claim 10, wherein the visual mark is at least one of the size, location or shape of the at least one of the electrodes.

12. The method according to claim 11, wherein the visual mark is a shape formed within the boundaries of the at least one of the electrodes.
